(19) United States
(12) Patent Application Publication
(10) Pub. No.: US 2006/0011300 A1
(43) Pub. Date: Jan. 19, 2006

(54) Device for treating semiconductor substrate

(76) Inventors: Jong-Bok Kim, Gyeonggi-do (KR); Sung-Ho Cha, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/177,254

(22) Filed: Jul. 7, 2005

(30) Foreign Application Priority Data
Jul. 19, 2004 (KR) 2004-55998

(51) Int. Cl. H01L 21/306

(52) U.S. Cl. 156/345.51; 156/345.31; 156/345.12

(57) ABSTRACT

Disclosed is a device for treating a semiconductor substrate. The device comprises a rotational support plate in which at least one mounting recess is formed at the periphery thereof, and support blocks disposed on the periphery of the support plate within said mounting recess for supporting the semiconductor substrate. Each of the support blocks comprises a positioning portion on which the semiconductor substrate is positioned. An insertion portion which has a shape complementary to the shape of the mounting recess is disposed under the positioning portion where it is inserted into the mounting recess.

### CROSS-REFERENCE TO RELATED APPLICATIONS

This U.S. non-provisional patent application claims priority under 35 U.S.C. § 119 of Korean Patent Application 2004-55998 filed on Jul. 19, 2004, the entire contents of which are hereby incorporated by reference.

### BACKGROUND OF THE INVENTION

The present invention relates to a device for manufacturing a semiconductor substrate, and more particularly to a device for performing a cleaning process to a semiconductor substrate.

A semiconductor device manufacturing process is typically associated with a deposition process in which a thin film layer is formed on a wafer and an etching process in which fine circuit patterns are formed on the thin film layer. Until circuit patterns required on the wafer are formed, the processes are repeated, and many curvatures are formed on the surface of the wafer. As the semiconductor is highly integrated, the line width of the circuit is reduced, and more wires are stacked on one chip and the step difference according to the positions in the chip is increased. The step difference generated by the stacking wires makes uniform coating of the conductor layer in the following process difficult, and problems such as defocus in the photographing process or the like are generated.

In order to solve the above problems, a process in which the surface of the wafer is flattened is required. Recently, since the wafer has become larger, a CMP (chemical mechanical polishing) method is mainly used to obtain an excellent flattening rate in a wide range flattening.

The CMP equipment has a polishing portion which performs a polishing process to the wafer, and a cleaning portion which performs a cleaning process to the wafer after polishing the wafer. The cleaning process comprises a chemical liquid treating process which etches and ablates contamination materials on the wafer by chemical reactions which uses chemical liquid such as fluorine acid, ammonia, and SC-1 (a liquid mixture of ammonia, hydrogen peroxide, and deionized water), a rinsing process in which the semiconductor wafer which is treated by the chemical liquid is rinsed by using a deionized water, and a drying process in which the wafer is dried finally.

Various devices are used to perform the cleaning process. One of such a device comprises a rotational support plate which has a plurality of arms, and support blocks on which a wafer is positioned are installed at the end portions of the arms. The support blocks are positioned on a flat upper surface of the arms, and are fixed by two screws inserted from a bottom of the support plate. The support plate is rotated at a high speed during the process. The loads applied to the engaging portion of the support blocks and the support plate are concentrated on a head portion of the screws during the rotation. Therefore, the screws are frequently damaged, and the operation rate of the equipment is lowered by the frequent changes of the screws.

The above-mentioned device can be used in one or plural processes among the chemical liquid treating process, the rinsing process, and the drying process. If the chemical liquid treating process which is processed at a high temperature and the drying process which is processed at an ordinary temperature are processed simultaneously, the screws are more easily damaged by the periodic thermal stress of the screws.

### SUMMARY OF THE INVENTION

The present invention is directed to a substrate treating device which can prevent the damage of members which engage a support plate and support blocks due to the concentrations of loads.

A device for treating a semiconductor substrate is provided. This device comprises a rotational support plate in which at least one mounting recess is formed at the periphery thereof. Support blocks are disposed on the periphery of the support plate within the mounting recess for supporting the semiconductor substrate. Each of the support blocks comprises a positioning portion on which the semiconductor substrate is positioned, and an insertion portion which has a shape complementary to the shape of the mounting recess and is disposed under the positioning portion where it is inserted into the mounting recess.

Preferably, the mounting recess is formed so as to be extended to the side surface of the support plate and the support block is moved into the mounting recess. At least one portion of the side surfaces which form the mounting recess preferably makes contact with an upper portion of the insertion portion when it is inserted into the mounting recess. The side surface which forms the mounting recess preferably comprises inclined sides and a wider lower portion, and the cross-section of the mounting recess comprises inclined sides and a wider lower portion. The mounting recess preferably comprises an upper portion which has a uniform cross-section and a lower portion which has a uniform cross-section, the cross-section of the lower portion of the mounting recess being wider than that of the cross-section of the upper portion of the mounting recess. The support plate preferably comprises a center portion, and arms which are joined to and extend from the center portion, the mounting recesses being formed in the arms.

The device further preferably comprises at least one engaging member which joins the insertion portion and the mounting recess. The engaging member is preferably at least one screw. The engaging member is preferably made of a high temperature polymer, more preferably polyvinyl chloride.

The treatment of the semiconductor substrate preferably comprises at least one of a chemical liquid treating process, a rinsing process, and a drying process. Moreover, a device for treating a semiconductor substrate can be provided which comprises a polishing portion which performs a polishing process to the semiconductor substrate and a cleaning portion disposed on a side of the polishing portion, for cleaning the semiconductor substrate on which the polishing process is performed. The cleaning portion can comprise a cleaning device chemically treating and for drying the semiconductor substrate. The cleaning device can further comprise a rotational support plate in which at least one mounting recess is formed at the periphery thereof, support blocks disposed on the periphery of the support plate the mounting recess for supporting the semiconductor substrate, and a nozzle portion which supplies a chemical material onto the semiconductor substrate supported by the support blocks. Each of the support blocks can further comprise a positioning portion on which the semiconductor substrate is positioned, and an insertion portion having a shape complementary to the shape of the mounting recess and disposed under the positioning portion where it is inserted into the mounting recess.

moved

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention. In the drawings:

FIG. 1 is a view for schematically showing the structure of a substrate treating device according to a preferred embodiment of the present invention;

FIG. 2 is a front view of a cleaning device of FIG. 1;

FIG. 3 is a perspective view for showing a support plate and support blocks of FIG. 2;

FIG. 4 is a view illustrating a state in which a latch is in a locked position;

FIG. 5 is a view illustrating a state in which a latch is in an open position;

FIG. 6 is a perspective view illustrating a preferred mounting recess of the support plate and an insertion portion of a support block; and

FIG. 7 is a perspective view illustrating another preferred mounting recess of the support plate and an insertion portion of a support block.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the invention to those skilled in the art. Like numerals refer to like elements throughout the specification.

Hereinafter, it will be described about an exemplary embodiment of the present invention in conjunction with the accompanying drawings.

In the following embodiments, a substrate treating device comprises a cleaning portion 30 and a polishing portion 40, and equipment for chemically and mechanically polishing a semiconductor substrate will be described. However, it is an example of preferred embodiments, and the spirit of the present invention can be applied to all devices which have a rotational support plate 100 and a support block which is engaged with the support plate 100 and supports a wafer. For example, the substrate treating device of the present invention can be a device which performs a cleaning process, such as a chemical liquid treating process, a rinsing process, and a drying process, or a device which performs different processes.

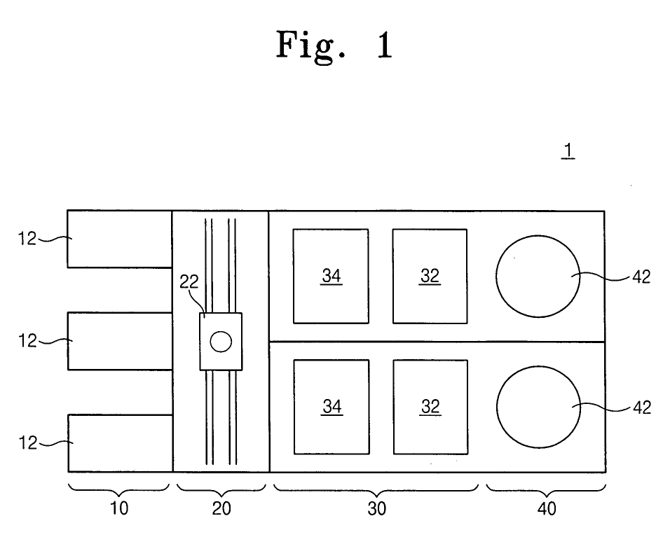

FIG. 1 is a view for schematically showing the structure of a substrate treating device according to a preferred embodiment of the present invention. Referring to FIG. 1, the device comprises a loading/unloading portion 10, a transferring portion 20, a cleaning portion 30, and a polishing portion 40. Buffer portions 12 in which cassettes for receiving wafers are positioned are disposed in the loading/unloading portion 10. At least one polishing device is disposed in the polishing portion 40, and the polishing device 42 has a platen (not shown) to which a polishing pad (not shown) is attached and a polishing head which fixes a wafer and presses the wafer on the polishing pad (not shown). A device for polishing a wafer by using a polishing pad and a polishing head is well known in the art, and explanation of the device is omitted. The number of the polishing devices 42 can be one or a plurality. In the preferred embodiment, two polishing devices are provided.

A cleaning portion 30 is disposed on one side of the polishing portion 40. The cleaning portion has at least one cleaning device 32 and 34. The cleaning portion 30 performs a chemical liquid treating process, a rinsing process, and a drying process to a wafer to which a polishing process is completed. The chemical liquid treating process is performed by sequentially using a plurality of chemical liquids. For example, the chemical liquid which is used in the chemical liquid treating process can be fluorine acid, ammonia, or SC-1 (a liquid mixture of ammonia, hydrogen peroxide, and deionized water). Two cleaning device 32 and 34 are provided in one polishing device 42. In the cleaning device 32 adjacent to the polishing device 42, the chemical liquid treating process can processed by sequentially using a first chemical liquid and a second chemical liquid. In the other cleaning device, a chemical liquid treating process by a third chemical liquid, a rinsing process by deionized water, and a drying process can be performed. The first through third chemical liquid can be one of fluorine acid, ammonia, and SC-1. Although not shown in the figures, a transferring robot for transferring wafers between the polishing device 42 and the cleaning devices 32 and 34 is provided in the polishing portion 40 and the cleaning portion 30. Differently from the above-described example, one cleaning device can perform the above-mentioned processes, or more cleaning devices can performs one process in one cleaning device. The transferring portion 20 is disposed between the cleaning portion 20 and the loading/unloading portion 10, and a transferring robot 22 for transferring a wafer is installed in the transferring portion 20. The structure of the above-described substrate treating device is merely an example of the present invention, the loading/unloading portion 10, the transferring portion 20, the cleaning portion 30, and the polishing portion can be disposed differently form this structure.

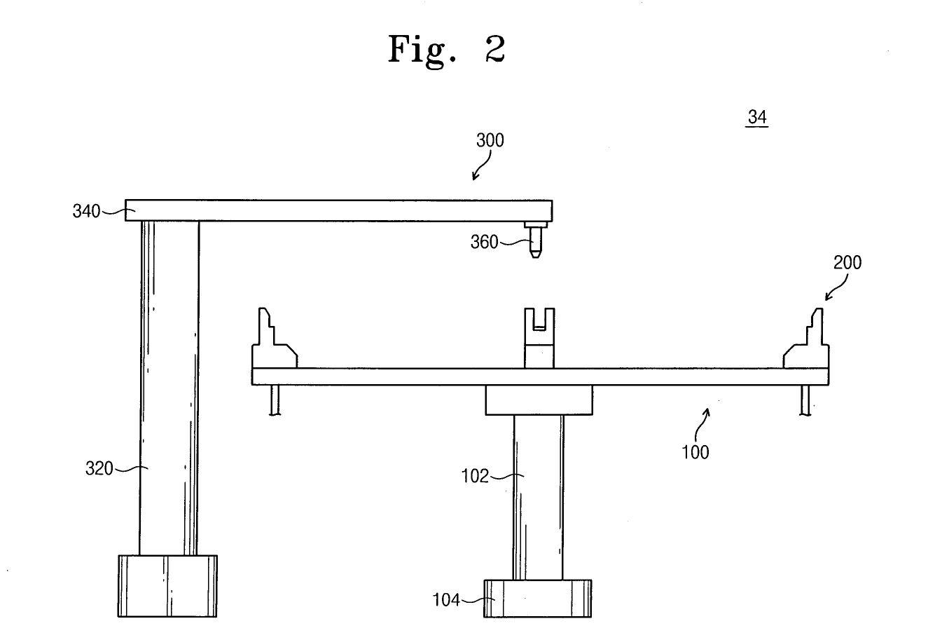

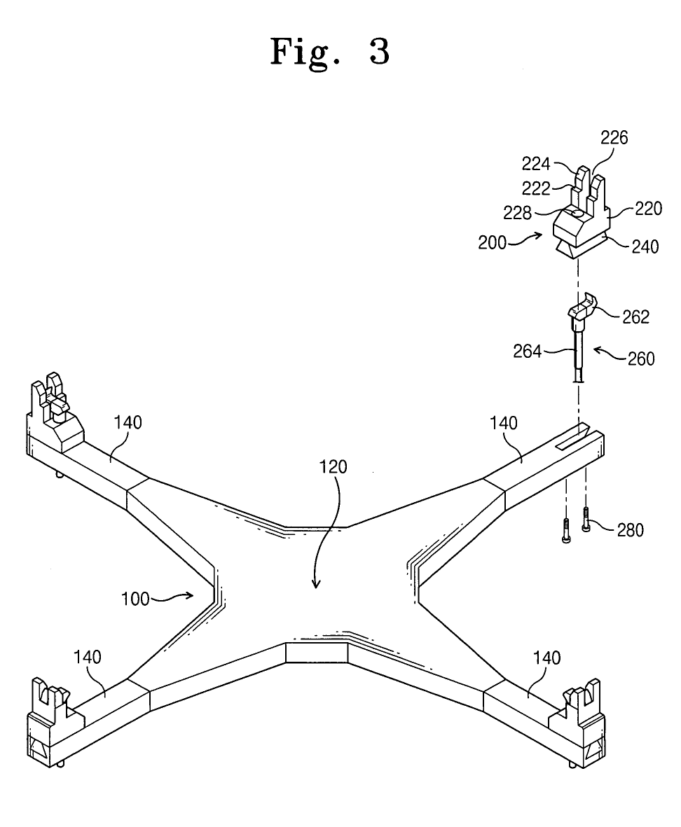

FIG. 2 is a front view for showing a cleaning device 34 which performs a drying process, and FIG. 3 is a perspective view for showing the support plate 100 and the support block 200 of FIG. 2. Referring to FIGS. 2 and 3, the cleaning device 34 has the support plate 100, the support block 200, and a nozzle portion 300. The support plate 100 has a center portion 120 of disc-shape, and a plurality of arms which is extended outwardly from the center portion. According to the present invention, the support plate 100 has four arms which are disposed at a substantially constant angle, each of the rod arms 140 has a rod shape. A rotating shaft 102 rotated by a motor 104 is engaged with the bottom surface of the support plate 100, and the nozzle portion 300 is disposed at an upper portion of the support plate. The nozzle portion 300 is vertically disposed on one side of the support plate 100, and has a rotational support shaft 320. A support arm 340 is horizontally engaged with the tip end portion of the support shaft 100, and a nozzle 360 for supplying the chemical liquid or the deionized water is connected to the bottom surface of the end of the support arm 340. The number of the nozzle portions 300 can be one or a plurality.

The support block 200 is installed on the upper surface of the end of each of the arm. The support block 200 has a positioning portion 220 on which a wafer is positioned. The positioning portion 220 has a contacting portion 222 which is positioned at the periphery of the wafer and a guide portion 224 which guides the water to a proper position. The contacting portion 222 is flatly formed, and the guide portion 224 is formed such that it is inclined from the end of the contacting portion 222 towards the upper portion. An opening 226 which is penetrated in the radial direction of the wafer is formed at the center portion of the contacting portion 222 and the guide portion 224. If a peripheral portion of the wafer transferred by the robot is positioned on the guide portion 224, the wafer moves downwardly along the guide portion 224, and the periphery of the wafer is positioned on the contacting portion 222. According to the preferred embodiment of the present invention, the wafer is supported by four support blocks 200. Selectively, three or more than five arms 140 can be provided, and the wafer can be supported by three or more than five support blocks 200.

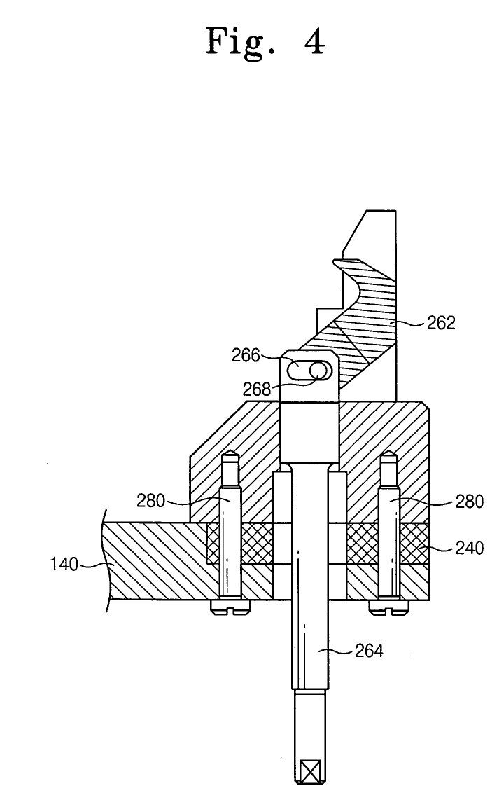

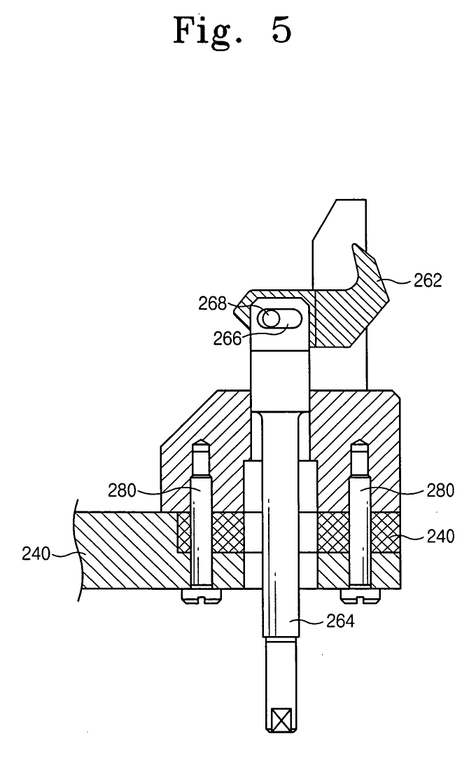

A hole 228 which is vertically penetrated is formed at the center portion of the support block 200, and a fixing member 260 which fixes the wafer positioned on the support block 200 is inserted into the hole 228. The fixing member 260 has a structure in which the fixing member can be moved upwardly and downwardly by a predetermined distance. The fixing member 260 has a latch 262, a vertical rod 264 engaged with the latch 262, and a driving portion which drives the vertical rod 264 upwardly and downwardly. The latch 262 has a hook shape of a large radius of curvature. Preferably, the latch 262 has a shape which corresponds to a predetermined portion of the contacting wafer. A hole 266 is horizontally formed in the vertical rod, and a pivot 268, which engages the latch 262 and the vertical rod 264, is inserted into the hole 266. By the upward and downward movement of the vertical rod 264, the pivot 268 is moved in the hole 266 by a predetermined distance, and the latch 262 is rotated through the opening 226 formed in the guide portion 224. By the rotation, the latch 262 is moved between a locking position, at which it makes contact with the side surface and the upper surface of the wafer, and an opening position, at which it is pushed outwardly of the support block 200 through the opening formed in the guide portion. FIG. 4 is a view for showing a state in which the latch 262 is at the locking position by the downward movement of the vertical rod 264, and FIG. 5 is a view for showing a state in which the latch 262 is at the opening position by the upward movement of the vertical rod 264.

The upper surface of the arm 140 is flatly formed, and the support block 200 can be engaged with the upper surface of the arm 140 by screws 280. However, in this case, when the support plate 100 is rotated at a high speed, the load is concentrated on the screws 280. If the chemical liquid treating process is performed at a high temperature, the drying process is processed at an ordinary temperature, or the like are periodically processed, the screws 280 are easily damaged by the thermal stress. In order to prevent such damage, in a preferred embodiment, a mounting recess 160 is formed at the peripheral portion of each of the arms 140, and the support block 200 has an insertion portion 240 which is extended from the lower portion of the positioning portion 220 and inserted into the mounting recess 160. The mounting recess 160 is formed on the upper surface of the arm 140 and is extended to the side surface of the arm 140. The mounting recess 160 is arranged lengthwise along the arm 140 such that the longitudinal cross-section is constant, and the insertion portion 240 has a shape corresponding to the mounting recess 160. As the insertion portion 240 is moved from the end of the arm 140 towards the inner side of the arm 140, the support block 200 is engaged with the arm 140. If the insertion portion 240 is inserted into the mounting recess 160, the support block 200 is fixed to the arm 140 by engaging members. The screws 280 can be used as the engaging members, and a plurality of, preferably at least two, screws 280 can be provided. The screws 280 can be inserted from the bottom surface or the side surface of the arm 140, and can be inserted from the support block 200. In another embodiment, one screw 280 can be inserted from the bottom surface of the arm 140, and another screw can be inserted from the support block 200. The screws 280 are generally made of PEEK (polyether ether ketone) and are apt to be easily deteriorated. In the preferred embodiment, the screws 280 are made of HT-PVC (high temperature poly vinyl chloride) and are more durable to the effects of heat.

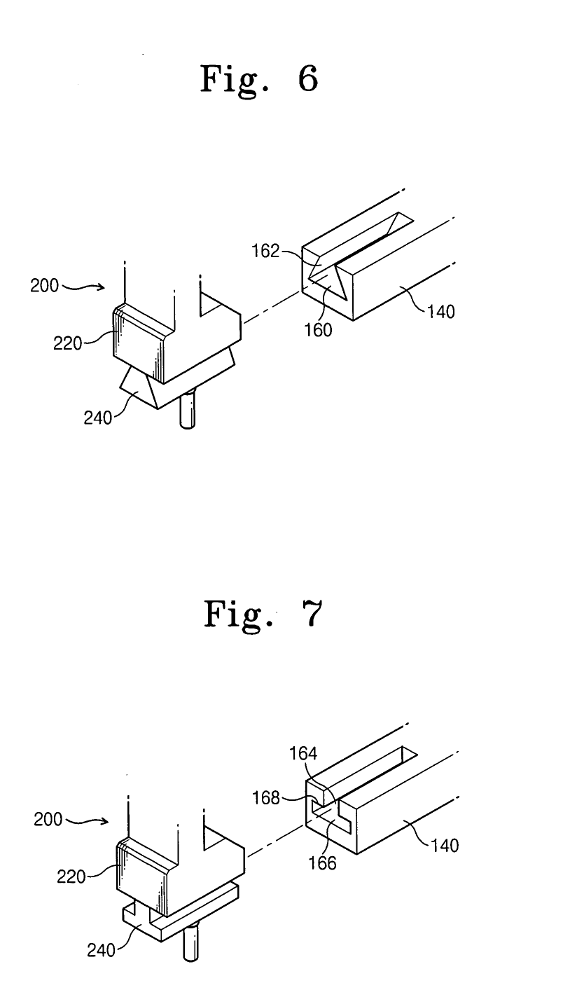

The insertion portion 240 of the support block 200 and the mounting recess 160 can be formed in various shapes. Since the insertion portion 240 has a shape corresponding to the mounting recess 160, only the shape of the mounting recess 160 will be explained. In the state in which the insertion portion 240 is inserted into the mounting recess 160, at least one portion of side surface which forms the mounting recess 160 makes contact with the insertion portion 240 at the upper portion of the insertion portion 240. FIG. 6 depicts the mounting recess 160 formed in the arm 140 and the insertion portion 240 of the support block 200 in FIG. 3. Referring to FIG. 6, the mounting recess 160 has an opened upper portion, a flat lower surface, and inclined surfaces 162 disposed on both sides. The inclined surfaces 162 is disposed so as to be opposite to each other, and is formed such that the area of the cross-section of the mounting recess 160 is gradually widened at the lower portion thereof. When the support plate 100 is rotated at a high speed, the load is uniformly distributed to the inclined surfaces 162 which make contact with the insertion portion 240 of the support block 200. Therefore, the load is not concentrated on the screws 280, and thus the life of the screws can be extended.

FIG. 7 is a view similar to FIG. 6 which shows another example of the shapes of the mounting recess 160 and the insertion portion 240. Referring to FIG. 7, the mounting recess 160 has a upper portion 164 and a lower portion 166. The upper portion 164 of the mounting recess 160 has a substantially uniform cross-section. The lower portion 166 is disposed under the upper portion 164, and has a substantially uniform cross-section. The border portion of the upper and lower portions is stepped, and the area of the cross-section of the lower portion 166 is wider than that of the upper portion 164. When the support plate 100 is rotated at a high speed, the load is uniformly distributed to the stepped portion, and a concentration of the load on the screws 280 can be prevented.

The shapes of the mounting recess 160 and the insertion portion 240 of the support block 200 which are shown in FIGS. 6 and 7 are merely examples of the present invention. The cleaning device 32 in which the chemical liquid treating process is conducted can have the same structure as the cleaning device in which the drying process or the like is performed, or it can have a different structure.

According to the present invention, the concentration of the load to the screws which engages the arm of the support plate and the support block during the processes can be substantially reduced, and thus the lowering of the equipment operation downtime due to frequent changes of the screws.

Although the present invention has been described in connection with the embodiment of the present invention illustrated in the accompanying drawings, it is not limited thereto. It will be apparent to those skilled in the art that various substitution, modifications and changes may be thereto without departing from the scope and spirit of the invention.

What is claimed is:

1. A device for treating a semiconductor substrate, which comprises:
a rotational support plate in which at least one mounting recess is formed at the periphery thereof; and
support blocks disposed on the periphery of the support plate within said mounting recess for supporting the semiconductor substrate,
each of the support blocks comprising a positioning portion on which the semiconductor substrate is positioned, and an insertion portion which has a shape complementary to the shape of the mounting recess and is disposed under the positioning portion so as to be inserted into the mounting recess.

2. The device as set forth in claim 1, wherein the mounting recess is formed so as to be extended to the side surface of the support plate and the support block is moved into the mounting recess.

3. The device as set forth in claim 2, wherein at least one portion of the side surfaces which form the mounting recess makes contact with an upper portion of the insertion portion when it is inserted into the mounting recess.

4. The device as set forth in claim 3, wherein the side surface which forms the mounting recess comprises inclined sides and a wider lower portion, and the cross-section of the mounting recess comprises inclined sides and a wider lower portion.

5. The device as set forth in claim 3, wherein the mounting recess comprises an upper portion which has a uniform cross-section and a lower portion which has a uniform cross-section, the cross-section of the lower portion of the mounting recess being wider than that of the cross-section of the upper portion of the mounting recess.

6. The device as set forth in claim 3, wherein the device further comprises at least one engaging member which joins the insertion portion and the mounting recess.

7. The device as set forth in claim 6, wherein the engaging member is at least one screw.

8. The device as set forth in claim 6, wherein the engaging member is made of a high temperature polymer.

9. The device as set forth in claim 3, wherein the support plate comprises a center portion, and arms that extend from the center portion, the mounting recesses being formed in said arms.

10. The device as set forth in claim 3, wherein said treatment of said semiconductor substrate comprises at least one of a chemical liquid treating process, a rinsing process, and a drying process.

11. A device for treating a semiconductor substrate, which comprises:
a polishing portion which performs a polishing process to said semiconductor substrate; and
a cleaning portion disposed on a side of the polishing portion, for cleaning the semiconductor substrate on which the polishing process is performed,
wherein the cleaning portion comprising a cleaning device chemically treating and for drying said semiconductor substrate,
wherein the cleaning device comprising a rotational support plate in which at least one mounting recess is formed at the periphery thereof, support blocks disposed on the periphery of the support plate said mounting recess for supporting the semiconductor substrate, and a nozzle portion which supplies a chemical material onto the semiconductor substrate supported by the support blocks,
wherein each of the support blocks comprising a positioning portion on which the semiconductor substrate is positioned, and an insertion portion having a shape complementary to the shape of the mounting recess and disposed under the positioning portion where it is inserted into the mounting recess.

12. The device as set forth in claim 11, wherein the mounting recess is formed so as to be extended to the side surface of the support plate and the support block is moved into the mounting recess.

13. The device as set forth in claim 12, wherein at least one portion of the side surfaces which form the mounting recess makes contact with an upper portion of the insertion portion when it is inserted into the mounting recess.

14. The device as set forth in claim 13, wherein the side surface which forms the mounting recess comprises inclined sides and a wider lower portion, and the cross-section of the mounting recess comprises inclined sides and a wider lower portion.

15. The device as set forth in claim 13, wherein the mounting recess comprises an upper portion which has a generally uniform cross-section and a lower portion which has a uniform cross-section, the cross-section of the lower portion of the mounting recess being wider than that of the cross-section of the upper portion of the mounting recess.

16. The device as set forth in claim 13, wherein the device further comprises at least one engaging member which joins the insertion portion and the mounting recess.

17. The device as set forth in claim 16, wherein the engaging member is at least one screw.

18. The device as set forth in claim 16, wherein the engaging member is made of a high temperature polymer.

19. The device as set forth in claim 13, wherein the support plate comprises a center portion, and arms that extend from the center portion, the mounting recesses being formed in said arms.

20. A method for treating a semiconductor substrate, which comprises:
providing a rotational support plate in which at least one mounting recess is formed at the periphery thereof, and support blocks disposed on the periphery of the support plate within said mounting recess for supporting the semiconductor substrate,
each of the support blocks comprising a positioning portion on which the semiconductor substrate is positioned, and an insertion portion which has a shape complementary to the shape of the mounting recess and is disposed under the positioning portion for insertion into the mounting recess;
positioning the semiconductor substrate on the support blocks; and
introducing the insertion portion into the mounting recess.
